(19) United States
(12) Patent Application Publication
(10) Pub. No.: US 2008/0188016 A1
(43) Pub. Date: Aug. 7, 2008

(54) Die detection and reference die wafermap alignment

(75) Inventors: Melanie Aquitania Pare, Baguio City (PH); Teofilo Froilando Alcantara Bibit-Chee, Baguio City (PH); Mary Amelia Aquino Monis, Baguio City (PH); Melvin B. Alviar, Baguio City (PH); James Raymond Baello, Quezon City (PH); Antonio Rosario Taloban, Baguio City (PH)

Correspondence Address: TEXAS INSTRUMENTS INCORPORATED, P O BOX 655474, M/S 3999, DALLAS, TX, 75265, US

(73) Assignee: Texas Instruments, Inc.

(21) Appl. No.: 11/701,681

(22) Filed: Feb. 2, 2007

(51) Int. Cl. H01L 21/66

(52) U.S. Cl. 438/16; 257/E21.525

(57) ABSTRACT

One embodiment of the present invention includes a method for aligning a wafermap with a semiconductor wafer. The method may comprise assigning a location code to each of a plurality of dies on the wafermap. Each of the plurality of dies on the wafermap can correspond to each of a plurality of dies on the semiconductor wafer. The method may also comprise scanning an approximate location of a reference die on the semiconductor wafer with a die detection sensor based on the location code corresponding to a location of the reference die on the wafermap and determining a physical location of the reference die on the semiconductor wafer using the die detection sensor. The method may further comprise correlating the physical location of the reference die on the semiconductor wafer with the respective location code corresponding to the reference die on the wafermap.

### TECHNICAL FIELD

This invention relates to integrated circuit production, and more specifically to die detection and reference die wafermap alignment.

### BACKGROUND

In an integrated circuit (IC) manufacturing process, a number of IC dies are manufactured together on a single semiconductor wafer. After each of the dies on the semiconductor wafer are tested, the test data can be recorded on a wafermap. For example, the wafermap can include a computer-based image having a color-code that demonstrates which of the dies on the corresponding semiconductor wafer are acceptable and which of the dies are rejects. Upon conclusion of the testing, the acceptable dies can be picked from the semiconductor wafer and placed in an IC package using a die collet. The motion of the die collet can be controlled by a computer algorithm. Thus, the wafermap is aligned with the semiconductor wafer prior to the pick-and-place operation, such that the computer algorithm is able to correlate which of the dies on the semiconductor wafer are the acceptable dies and which of the dies are the rejected dies.

To correlate the wafermap with the semiconductor wafer, a reference die can be designated on both the wafermap and the semiconductor wafer. For example, the location of the reference die on the wafermap can correspond to the location of the reference die on the semiconductor wafer. As the motion of the die collet can be based on the known coordinates of the dies on the wafermap, the computer algorithm can thus control the die collet to pick-and-place the correct dies based on the common location of the reference die on the wafermap relative to the semiconductor wafer. Typically, the reference die is designated on the semiconductor wafer manually by a technician. However, such manual designation can be prone to human error, which can result in a shifted map. As a result, the die collet can be unintentionally commanded to pick rejected dies, which reduces yield and adds time and cost to the IC manufacturing process.

### SUMMARY

One embodiment of the present invention includes a method for aligning a wafermap with a semiconductor wafer. The method may comprise assigning a location code to each of a plurality of dies on the wafermap. Each of the plurality of dies on the wafermap can correspond to each of a plurality of dies on the semiconductor wafer. The method may also comprise scanning an approximate location of a reference die on the semiconductor wafer with a die detection sensor based on the location code corresponding to a location of the reference die on the wafermap and determining a physical location associated with the reference die on the semiconductor wafer using the die detection sensor. The method may further comprise correlating the physical location associated with the reference die on the semiconductor wafer with the respective location code corresponding to the reference die on the wafermap.

Another embodiment of the present invention includes an wafermap alignment system. The system may comprise a die detection sensor configured to sense an image pattern associated with four corners of a plurality of dies on a semiconductor wafer and a memory configured to store data representing a predetermined image pattern associated with four corners of a model die and a location code associated with a location of at least one reference die on a wafermap. The system may also comprise a controller configured to implement a die detection algorithm to determine a physical location associated with the at least one reference die based on a comparison of the image pattern associated with the four corners of the plurality of dies with the predetermined image pattern. The controller may also be configured to correlate the physical location associated with the at least one reference die with the location code associated with the location of the at least one reference die on the wafermap.

Another embodiment of the present invention includes a method for aligning a wafermap with a semiconductor wafer. The method may comprise assigning a location code to each of a plurality of dies on the wafermap. Each of the plurality of dies on the wafermap can correspond to each of a plurality of dies on the semiconductor wafer. The method may also comprise scanning an approximate location of a partial die on the semiconductor wafer with a die detection sensor based on the location code corresponding to a location of the partial die on the wafermap. The partial die can be adjacent to a reference die on the semiconductor wafer. The method may also comprise determining a physical location associated with the partial die and determining a physical location associated with the reference die on the semiconductor wafer based on the physical location of the partial die and a predetermined pattern of dies arranged near the location associated with the partial die. The method may further comprise correlating the physical location associated with the reference die on the semiconductor wafer with the respective location code corresponding to the reference die on the wafermap.

### BRIEF DESCRIPTION OF THE DRAWINGS

FIG. 1 illustrates an example of an automatic wafermap alignment system in accordance with an aspect of the invention.

FIG. 2A illustrates an example of a semiconductor wafer in accordance with an aspect of the invention.

FIG. 2B illustrates another example of a semiconductor wafer in accordance with an aspect of the invention.

FIG. 3 illustrates an example of a diagram depicting the operation of a die detection algorithm in accordance with an aspect of the invention.

FIG. 4 illustrates another example of a diagram depicting the operation of a die detection algorithm in accordance with an aspect of the invention.

FIG. 5 illustrates an example of a diagram depicting the operation of a wafermap alignment algorithm in accordance with an aspect of the invention.

FIG. 6 illustrates a method for automatically aligning a wafermap with a semiconductor wafer in accordance with an aspect of the invention.

### DETAILED DESCRIPTION

The present invention relates to integrated circuit production, and more specifically to die detection and reference die wafermap alignment. A location code is assigned to each of a plurality of dies on a wafermap, with each location code corresponding to a physical location of each of a plurality of dies on a semiconductor wafer. A die detection sensor can be commanded to sense an approximate location of a reference die based on the location code corresponding to the location of the reference die on the wafermap. As an example, the approximate location can be a location of a partial die located adjacent to the reference die. The physical location of the reference die can be determined based on a pattern recognition comparison of four-corners of each of the dies in the approximate location with a trained die pattern. In addition, reference die pairs can be designated in the extreme rows and/or columns to verify a theta count corresponding to a number of rows and/or columns of the semiconductor wafer.

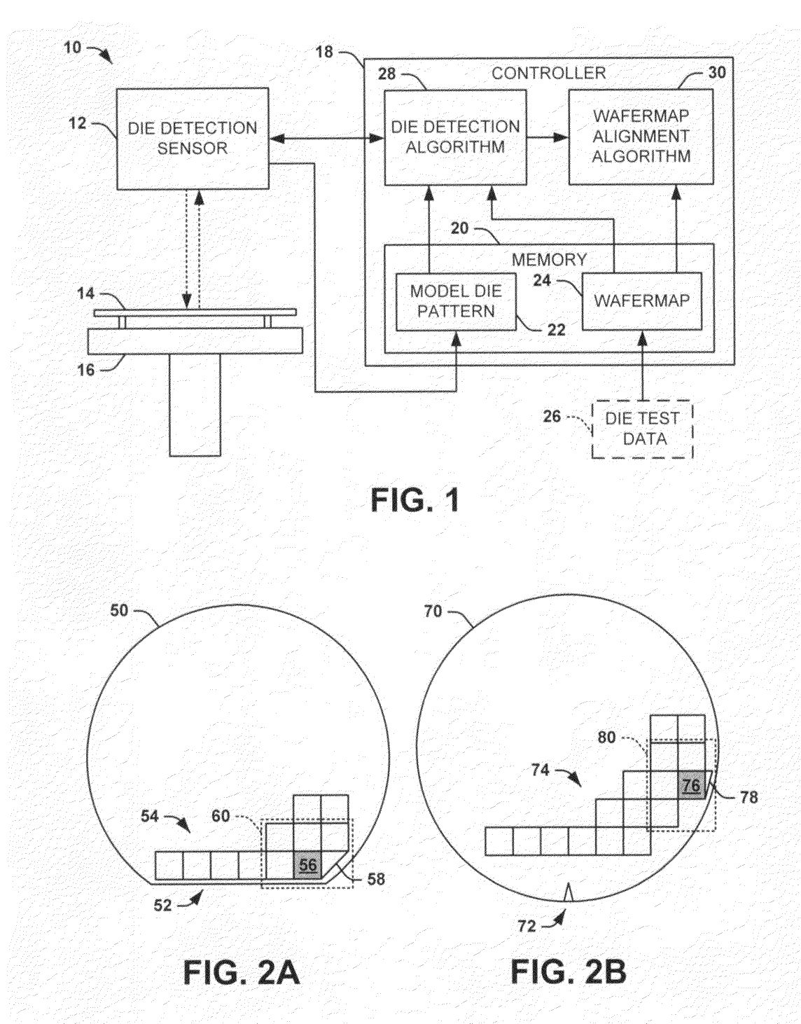

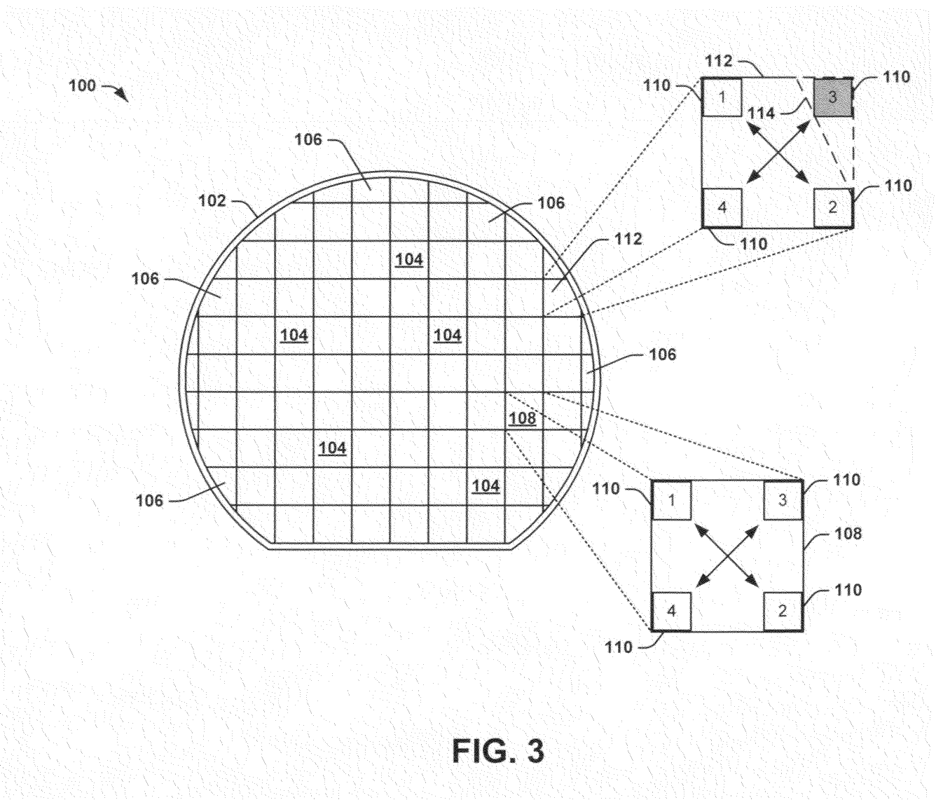

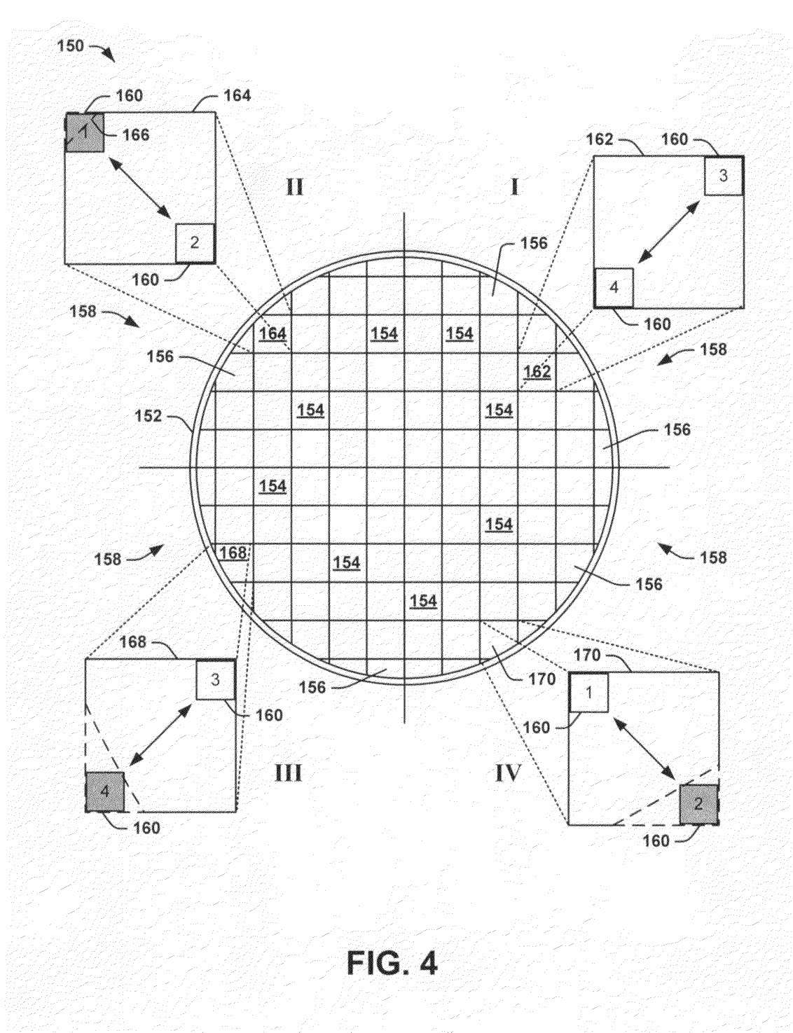

FIG. 1 illustrates an example of an automatic wafermap alignment system 10 in accordance with an aspect of the invention. The wafermap alignment system 10 includes a die detection sensor 12 configured to scan a semiconductor wafer 14 that is situated on a wafer stage 16. The semiconductor wafer 14 can include a plurality of dies that have been manufactured in an integrated circuit (IC) manufacturing process. As an example, the die detection sensor 12 can include an illumination source (not shown) and an optical sensor (not shown), such that the surface of the semiconductor wafer 14 can be illuminated and a pattern image associated with a given one of the dies can be reflected back to the sensor. The pattern image can include windows situated at the corners of the each of the dies, as is explained in greater detail below with reference to FIGS. 3 and 4.

The wafermap alignment system 10 also includes a controller 18. The controller 18 includes a memory 20 that is configured to store data representative of a model die pattern 22. In the example of FIG. 1, the model die pattern 22 is demonstrated as obtained from the die detection sensor 12. For example, the die detection sensor 12 can obtain a predetermined image from a die that is known to be a complete, acceptable (i.e., not rejected) die using a requisite amount of illumination. As a result, the model die pattern 22 can be a reliable image for which die pattern images associated with subsequent dies can be compared. As an example, the model die pattern 22 can be obtained as part of an automatic process, such as from a known acceptable die on a previously aligned semiconductor wafer 14, or can be obtained manually by an operator of the wafermap alignment system 10. As another example, a simulated die pattern image representative of a model die can be provided.

The memory 20 can also be configured to store a wafermap 24. The wafermap 24 can be a graphical computer representation that corresponds to the semiconductor wafer 14. For example, the wafermap 24 can include a plurality of dies, each corresponding directly to respective ones of the plurality of dies on the semiconductor wafer 14. The plurality of dies on the wafermap 24 are thus representative of the expected physical location of the plurality of dies on the semiconductor wafer 14 relative to each other. Each of the dies on the wafermap 24 can include a location code. For example, the location code can be binary, decimal, hexadecimal, or any of a variety of other types of codes representing a unique location of the respective die. As such, the location code for a given die on the wafermap 24 also corresponds to a respective corresponding die having the same relative unique location on the semiconductor wafer 14.

In addition, die test data 26 that is associated with the semiconductor wafer 14 can be loaded into the memory 20, such as from testing equipment in a previous stage of the semiconductor wafer manufacturing process. The die test data 26 can be indicative of which of the plurality of dies on the semiconductor wafer 14 are acceptable dies, and which of the plurality of dies on the semiconductor wafer 14 are unacceptable, and thus reject dies. The die test results 26 can be sorted based on the location codes for each of the respective dies on the wafermap 24. Therefore, the die test results 26 can be incorporated into the wafermap 24 to indicate the status of the dies on the semiconductor wafer 14. It is to be understood that the wafermap 24 and the die test results 26 may not be separate, but could instead be incorporated together.

At least one die on the semiconductor wafer 14 can be designated as a reference die, such that the wafermap 24 can include a reference die in the corresponding location. Therefore, the common location of the reference die between the wafermap 24 and the semiconductor wafer 14 can serve as a basis to align the wafermap 24 to the semiconductor wafer 14. Accordingly, the location of each of the acceptable dies and each of the rejected dies on the semiconductor wafer 14 can be known by the controller 18 based on their corresponding locations on the wafermap 24. As a result, pick-and-place hardware (not shown) can selectively pick up the acceptable dies from the semiconductor wafer 14, based on their known positions due to the alignment of the wafermap 24 with the semiconductor wafer 14 and the respective location codes of the aligned dies, and can be placed in IC packages. Therefore, without successful alignment of the wafermap 24 with the semiconductor wafer 14, the wafermap 24 can be shifted by one or more dies in a given direction.

In order to locate the reference die on the semiconductor wafer 14, such that the wafermap 24 can be successfully aligned with the semiconductor wafer 14, the controller 18 includes a die detection algorithm 28. The die detection algorithm 28 can be configured to provide commands to the die detection sensor 12 to scan the plurality of dies on the semiconductor wafer 14. As an example, the die detection algorithm 28 can command the die detection sensor 12 to scan a location on the semiconductor wafer 14 that is an approximate location of the reference die based on accessing the wafermap 24 for the location code of the reference die and/or one or more surrounding partial or complete dies. As an example, the die detection sensor 12 could be commanded to physically move to the approximate location above the semiconductor wafer 14. As another example, the wafer stage 16 could be commanded to move the semiconductor wafer 14 to position the approximate location beneath the die detection sensor 12. As yet another example, the die detection sensor 12 could be commanded to position an optical scanning area at the approximate location on the semiconductor wafer 14. The die detection sensor 12 can thus scan the approximate location on the semiconductor wafer 14 to determine the physical location of the reference die based on a determined predetermined pattern of dies situated around the reference die. In addition, the die detection algorithm 28 can be configured to determine if a given scanned die is a complete die or a partial die, as explained below.

FIG. 2A illustrates an example of a first semiconductor wafer 50 in accordance with an aspect of the invention, and FIG. 2B illustrates an example of a second semiconductor wafer 70 in accordance with an aspect of the invention. The first semiconductor wafer 50 and the second semiconductor wafer 70 could each be separate types of semiconductor wafers 14 to which a respective wafermap 24 can be aligned, as described above in the example of FIG. 1. Therefore, in the description of the examples of FIGS. 2A and 2B, reference is to be made to the example of FIG. 1. In addition, it is to be understood that the first semiconductor wafer 50 and the second semiconductor wafer 70 are demonstrated as simplified examples, such that the first semiconductor wafer 50 and the second semiconductor wafer 70 are not intended to be limited to the examples of FIGS. 2A and 2B, respectively.

The first semiconductor wafer 50 is demonstrated in the example of FIG. 2A as having a flat truncation 52 at its bottom. As an example, the first semiconductor wafer 50 can be representative of a 200 mm semiconductor wafer. Similarly, the second semiconductor wafer 70 is demonstrated in the example of FIG. 2B as having a notch 72 at its bottom. As an example, the second semiconductor wafer 70 can be representative of a 300 mm semiconductor wafer. The flat truncation 52 and the notch 72 can be implemented to orient the first semiconductor wafer 50 and the second semiconductor wafer 70, respectively, on the wafer stage 16. As a result, the die detection sensor 12 can have a consistent orientation with respect to multiple ones of the first semiconductor wafer 50 and/or the second semiconductor wafer 70.

Each of the first semiconductor wafer 50 and the second semiconductor wafer 70 are demonstrated in the examples of FIGS. 2A and 2B as having a plurality of dies 54 and 74, respectively. It is to be understood that the examples of FIGS. 2A and 2B demonstrate only a portion of the plurality of dies 54 and 74, respectively, for simplicity sake, but that each of the first semiconductor wafer 50 and the second semiconductor wafer 70 can include many more dies than depicted. As described above in the example of FIG. 1, each of the plurality of dies 54 on the first semiconductor wafer 50 and each of the plurality of dies 74 on the second semiconductor wafer 70 can be represented by a respective wafermap 24. As such, each of the plurality of dies 54 on the first semiconductor wafer 50 and each of the plurality of dies 74 on the second semiconductor wafer 70 can have a location code associated with their relative positions.

In the example of FIG. 2A, the first semiconductor wafer 50 includes a reference die 56 that is situated adjacent to a partial/mirror die 58. It is to be understood that the partial/mirror die 58, in the example of FIG. 2A, could be implemented as a partial die, a mirror die, or both. The reference die 56, as demonstrated in the example of FIG. 2A, is located on the bottom-right amongst the plurality of dies 54, such that it is rightmost complete die above the flat truncation 52. Similarly, the second semiconductor wafer 70 includes a reference die 76 that is situated adjacent to a partial/mirror die 78. Similar to the partial/mirror die 58, the partial/mirror die 78 can be implemented as a partial die, a mirror die, or both in the example of FIG. 2B. The reference die 76, as demonstrated in the example of FIG. 2B, is located at a lower-right quadrant of the semiconductor wafer 70 amongst the plurality of dies 74. Although the example of FIG. 2B demonstrates that the reference die 76 is located on the bottom of the rightmost column, it is to be understood that the reference die 76 can be arranged in any of a variety of locations. For example, if multiple mirror dies aside from the partial/mirror die 78 are likewise located in the lower-right quadrant of the semiconductor wafer 70, the reference die 76 can be located at the mirror area nearest the notch 72. The locations of the reference die 56 and the reference die 76 can each be consistent from one of the first semiconductor wafer 50 to the next and from one of the second semiconductor wafer 70 to the next, respectively.

The partial/mirror die 58 on the first semiconductor wafer 50 and the partial/mirror die 78 on the second semiconductor wafer 70 can be given a location code on a respective wafermap 24, such as, for example, a null bin code. As a result, at the start of a wafermap alignment procedure, the controller 18 can command the die detection sensor 12 to scan an approximate location of the partial/mirror die 58 or the partial/mirror die 78 based on the bin code corresponding to the respective one of the partial/mirror die 58 or the partial/mirror die 78. As a result, scanning performed by the die detection sensor 12 is based on the approximate location of the respective reference die 56 or 76. The die detection sensor 12 can then scan the approximate area until it locates the partial/mirror die 56 or 76, upon which the controller 18 can record the position of the partial/mirror die. As a result, the controller 18 ascertains the position of the reference die 56 or 76 based on its adjacency with the respective partial/mirror die 58 or 78.

As there may be multiple partial/mirror dies near the approximate location of the partial/mirror die 58 or 78, the controller 18 may next verify the location of the reference die 56 or 76. As such, the controller 18 may command the die detection sensor 12 to scan the approximate area for a predetermined pattern of dies, demonstrated in the examples of FIGS. 2A and 2B, respectively, at 60 on the first semiconductor wafer 50 and at 80 on the second semiconductor wafer 70. The predetermined pattern of dies 60 or 80 can include any of a variety of arrangements that may be unique relative to the location of the respective reference die 56 or 76. Thus, the predetermined pattern of dies 60 or 80 can include any of a variety of arrangements of complete dies, partial dies, and/or mirror dies. Upon die detection sensor 12 detecting the predetermined pattern of dies 60 or 80 relative to the reference die 56 or 76, respectively, the location of the reference die 56 or 76 has been verified, such that the controller 18 can compute the physical location of the reference die 56 or 76 with certainty.

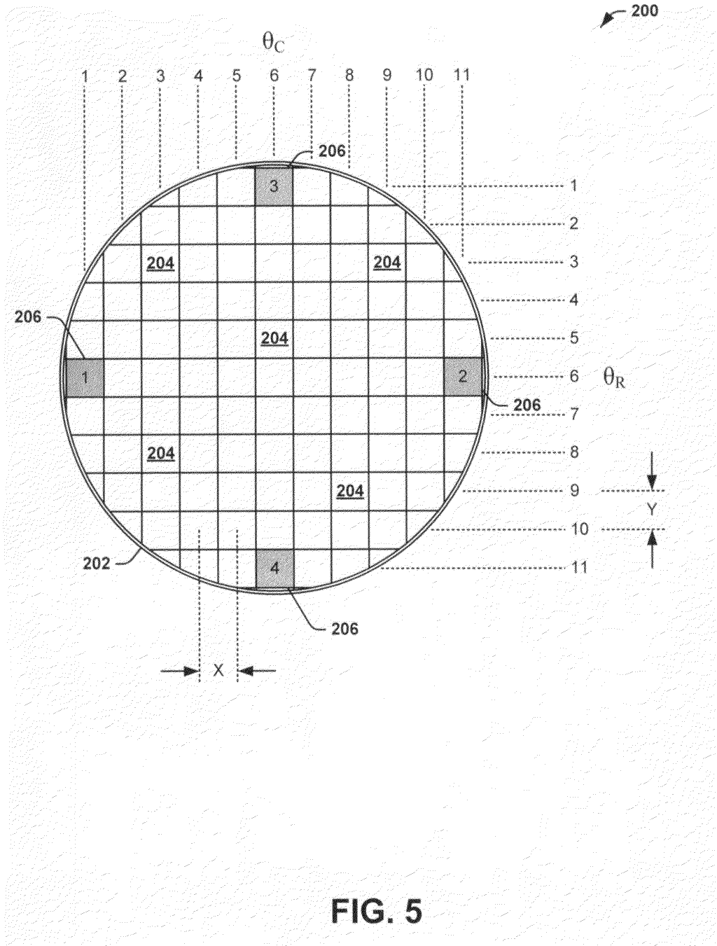

Referring back to the example of FIG. 1, upon the controller 18 determining the physical location of the reference die on the semiconductor wafer 14 via the die detection algorithm 28, the controller 18 implements a wafermap alignment algorithm 30. The wafermap alignment algorithm 30 accesses the wafermap 24 and assigns the location code corresponding to the reference die on the wafermap 24 to the physical location of the reference die on the semiconductor wafer 14. From that assignment, the wafermap alignment algorithm 30 can extrapolate the physical location of every one of the plurality of dies on the semiconductor wafer 14 and assign each of the plurality of dies a respective corresponding location code from the wafermap 24. Therefore, the controller 18 can identify which of the plurality of dies on the semiconductor wafer 14 are acceptable dies and which of the plurality of dies on the semiconductor wafer 14 are reject dies, based on, for example, the representation of the respective acceptable dies and the reject dies on the wafermap 24. In addition, the wafermap alignment algorithm 30 can also include verification steps, such that a number of rows and/or columns associated with the semiconductor wafer 14 can be verified with a number of rows and/or columns associated with the wafermap 24, as described in greater detail in the example of FIG. 5 below. Accordingly, associated pick-and-place hardware can pick the acceptable dies from the semiconductor wafer 14 without erroneously picking reject dies.

It is to be understood that the automatic wafermap alignment system 10 is demonstrated as merely an example in FIG. 1. As such, the automatic wafermap alignment system 10 is not intended to be limited to the example of FIG. 1. As an example, the controller 18 can control multiple die detection sensors 12, such that the memory 20 can store multiple wafermaps 24 corresponding to multiple semiconductor wafers 14. As another example, the automatic wafermap alignment system 10 can be included with other hardware in the IC manufacturing process, such as etching, testing, or pick-and-place hardware. Therefore, the automatic wafermap alignment system 10 can be arranged in any of a variety of different ways.

FIG. 3 illustrates an example of a diagram 100 depicting the operation of the die detection algorithm 28 in accordance with an aspect of the invention. The die detection algorithm depicted by the diagram 100 can be substantially similar to the die detection algorithm 28 in the example of FIG. 1. As such, reference is made to the example of FIG. 1 in the discussion of FIG. 3.

The diagram 100 includes a semiconductor wafer 102 that includes a plurality of complete dies 104. As demonstrated in the example of FIG. 3, the semiconductor wafer 102 also includes a plurality of partial dies 106, which are configured on the periphery of the semiconductor wafer 102. It may be important for the die detection sensor 12 in the example of FIG. 1 to detect partial dies 106. For example, as described above in the examples of FIGS. 1 and 2, the die detection algorithm 28 includes scanning for and detecting the partial/mirror die 58 or 78 to locate the respective reference die 56 or 76. As another example, the controller 18 can command the die detection sensor 12 to perform a Die/No-Die check to detect one or more pairs of complete dies 104 at extreme columns and/or rows of the semiconductor wafer 102, such as demonstrated with respect to the example of FIG. 5 below. As yet another example, it may be necessary to detect partial dies 106 during one or more stages of the IC manufacturing process.

The die detection algorithm 28 can include a gray-scale (e.g., 0-255 shade resolution) pattern recognition algorithm. The pattern recognition algorithm can, for example, compare a die pattern of a scanned die with a model die. As described above, the model die can be a die that is known to be complete and acceptable (i.e., not rejected). An image of the model die can thus be captured prior to scanning using an amount of illumination requisite for detection to generate the predetermined image pattern for comparison. As a result, the model die pattern can be a reliable image for which images associated with subsequent dies can be compared after scanning. For the comparison, the die detection algorithm 28 can generate a match score that is representative of how close a pattern match results from the comparison. The match score can be compared with a threshold, such that the scanned die can be identified as a complete die 104 if the match score exceeds the threshold, and can be identified as a partial die 106 if the match score is equal to or less than the threshold. As an example, the match score can have an associated default value (e.g., 70%), but can be programmable.

The diagram 100 includes a first die 108, demonstrated in the example of FIG. 3 as having an enlarged view. The first die 108 is a complete (i.e., not partial) die 104. As demonstrated in the example of FIG. 3, the partial dies 106 are situated at the periphery of the semiconductor wafer 102, such that the partial dies 106 are not complete based on missing one or more corners. Thus, when scanning to determine if a given die is a complete die 104 or a partial die 106, the corners of the scanned die may be the only portion of a given one of the dies that is necessary to scan. Therefore, the die detection algorithm 28 may provide a die pattern window 110 at each of four corners of an area of a complete die, demonstrated in the example of FIG. 3 as covering each of the four corners of the first die 108.

The die pattern windows 110 are demonstrated in the example of FIG. 3 as Windows 1 through 4, arranged such that Window 1 and Window 2 are arranged diagonally opposite each other and Window 3 and Window 4 arranged diagonally opposite each other. The die pattern windows 110 may be the only area of the die 108 that is scanned by the die detection sensor 12, such that the die pattern in the die pattern windows 110 are compared with the die pattern in substantially identical die pattern windows of a model die. Because the comparison is based only on the die pattern in the die pattern windows 110, as opposed to the die pattern across the entirety of the first die 108, less area of the first die 108 is compared. As a result, comparing only the die pattern in the die pattern windows can be more efficient than a comparison of a pattern across the entirety of the first die 108. In the example of FIG. 3, because the first die 108 is a complete die, the die pattern windows 110 cover each of the corners of the first die 108. As a result, a comparison of the first die 108 with the model die based on the die pattern windows 110 results in the first die 108 being identified as a complete die 104.

As another example, the diagram 100 also includes a second die 112, demonstrated in the example of FIG. 3 as likewise having an enlarged view. The second die 112 is a partial die 106, and is therefore missing a corner. A dashed line 114 represents the missing corner of the second die 112. The example of FIG. 3 demonstrates the die pattern windows 110 arranged at the corners of an outline of a complete die which is superimposed over the second die 112. Therefore, as depicted in the example of FIG. 3, Window 3 covers the area of the missing corner, as demonstrated by the shading of Window 3. Accordingly, a comparison of the second die 112 with the model die based on the die pattern windows 110 results in the second die 112 being identified as a partial die 106.

The die pattern windows 110 are not intended to be limited to that depicted in the diagram 100 in the example of FIG. 3. As an example, the die pattern windows 110 can be bigger or smaller than that demonstrated in the diagram 100, and may not be the same size of shape relative to each other. Also, the die pattern windows 110 may not be flush with the edges of a complete die 104, but could instead be configured a suitable distance away from the edges to merit whether the die is to be considered a complete die or a partial die. As an example, the IC on a given die may not extend to the edge of the die, such that some of the semiconductor material at the edge of the die can be missing, but can still be acceptable for a fully functional IC. Furthermore, the comparison of the die pattern windows 110 with substantially identical die pattern windows on a model die can be performed either aggregately, such that the matching score is an aggregation of the comparison of the four die pattern windows 110, or individually, such that a separate matching score can be generated from a comparison of each of the four die pattern windows 110.

FIG. 4 illustrates another example of a diagram 150 depicting the operation of the die detection algorithm 28 in accordance with an aspect of the invention. The die detection algorithm 28 depicted by the diagram 150 can be substantially similar to the die detection algorithm 28 in the example of FIG. 1. As such, reference is to be made to the example of FIG. I in the discussion of FIG. 4.

The diagram 150 includes a semiconductor wafer 152 that includes a plurality of complete dies 154, as well as a plurality of partial dies 156, such that they are configured on the periphery of the semiconductor wafer 152. As described above in the example of FIG. 3, the partial dies 156 are situated at the periphery of the semiconductor wafer 152, such that the partial dies 156 are not complete based on missing one or more corners. Thus, when scanning to determine if a given die is a complete die 154 or a partial die 156, the corners of the scanned die may be the only portion of a given one of the dies that is necessary to scan. However, the missing corner of a given partial die 156 can be specific to a location of the partial die 156 along the periphery of the semiconductor wafer 152. For example, a partial die 156 at the top-right of the semiconductor wafer 152 can be known to be missing its top-right corner. Therefore, the die detection algorithm 28 may divide the semiconductor wafer 152 into quadrants 158, demonstrated as Quadrants I-IV in the example of FIG. 4, arranged similar to a trigonometric unit circle with a coordinate center that is substantially at the center of the semiconductor wafer 152. Based on the quadrant 158 in which the die detection sensor 12 is scanning, the die detection algorithm 28 may assign two die pattern windows 160, diagonally opposite each other, to the given scanned die.

The die pattern windows 160 are demonstrated in the example of FIG. 4 for a given scanned die as Windows 1 and 2 or Windows 3 and 4, such that the respective windows in each window pair are arranged diagonally opposite each other. The die pattern windows 160 may be the only area of a given die that is scanned by the die detection sensor 12, such that the die pattern in the die pattern windows 160 is compared with the die pattern in substantially identical die pattern windows of a model die. Because the comparison is based only on the die pattern in two die pattern windows 160, as opposed to the die pattern across the entirety of a given die or even across four die pattern windows, such as described above in the example of FIG. 3, less area of the scanned die is compared. As a result, comparing only the die pattern in the two die pattern windows can be more efficient than a comparison of a die pattern across the entirety of a scanned die, or across four die pattern windows.

As an example, the diagram 150 includes a first die 162, demonstrated in the example of FIG. 4 as having an enlarged view in Quadrant I. The first die 162 is demonstrated in the example of FIG. 4 as a complete die 154. The controller 18 may have determined that the die detection sensor 12 is scanning a die located in Quadrant I, and thus the die detection sensor 12 only needs to scan the die pattern windows 160 at the two corners of the first die 162 that are specific to Quadrant I. Specifically, the die detection algorithm 28 specifies that Windows 3 and 4 are used to detect whether the first die 162 is a complete die 154 or a partial die 156 for Quadrants I and III. The die detection algorithm 28 specifies Windows 3 and 4 because the corners of the first die 162 covered by Windows 3 and 4 can define a line that intersects the portion of the periphery of the semiconductor wafer 152 that is defined by Quadrant I. Because the first die 162 is a complete die 154, a comparison of the first die 162 with the model die based on the die pattern windows 160 results in the first die 162 being identified as a complete die 154.

As another example, the diagram 150 also includes a second die 164, demonstrated in the example of FIG. 4 as likewise having an enlarged view in Quadrant II. The second die 164 is a partial die 156, and is therefore missing a corner. A dashed line 166 represents the missing corner portion of the second die 164 in Quadrant II. The example of FIG. 4 demonstrates the die pattern windows 160 arranged at the diagonally opposite corners of an outline of a complete die which is superimposed over the second die 164. Therefore, as depicted in the example of FIG. 4, Window 1 covers the area of the missing corner. Accordingly, a comparison of the second die 164 with the model die based on the die pattern windows 160 results in the second die 164 being identified as a partial die 156. In a like manner, the diagram 150 also demonstrates a third die 168 in Quadrant III and a fourth die 170 in Quadrant IV, each being partial dies 156. Thus, similar to the second die 164, Window 4 covers the missing corner of the third die 168 due to the third die 168 being located in Quadrant III, and Window 2 covers the missing corner of the fourth die 170 due to the fourth die 170 being located in Quadrant IV. Therefore, a comparison of the die pattern windows 160 of the third die 168 or the fourth die 170 with the similar die pattern windows on the model die can result in the third die 168 or the fourth die 170 being identified as a partial die.

The die pattern windows 160 are not intended to be limited to that depicted in the diagram 150 in the example of FIG. 4. As an example, the die pattern windows 160 can be bigger or smaller than that demonstrated in the diagram 150, and may not be the same size or shape relative to each other. Also, the die pattern windows 160 may not be flush with the edges of a complete die 154, but could instead be configured a suitable distance away from the edges to merit whether the die is to be considered a complete die or a partial die. Furthermore, the comparison of the die pattern windows 160 with substantially identical die pattern windows on a model die can be performed either aggregately, such that the matching score is an aggregation of the comparison of the two die pattern windows 160, or individually, such that a separate matching score can be generated from a comparison of each of the two die pattern windows 160. It is also to be understood that the die detection algorithm 28, in implementing either the four die pattern windows 110 in the example of FIG. 3 or the two die pattern windows in the example of FIG. 4, can be used in any of a variety of applications other than wafermap alignment. For example, implementation of the two die pattern windows 160 can be used during production of the semiconductor wafer 152, such as to verify the location of partial dies 156 around the entire periphery of the semiconductor wafer 152.

FIG. 5 illustrates an example of a diagram 200 depicting the operation of the wafermap alignment algorithm 30 in accordance with an aspect of the invention. The operation of the wafermap alignment algorithm depicted by the diagram 200 can be substantially similar to the wafermap alignment algorithm 30 in the example of FIG. 1. As such, reference is made to the example of FIG. 1 in the discussion of FIG. 5.

The diagram 200 includes a semiconductor wafer 202 including a plurality of dies 204. The semiconductor wafer 202 also includes four reference dies 206, numbered in the example of FIG. 5 as Reference Dies 1-4. Each of the four reference dies 206 are demonstrated in the example of FIG. 5 as located in each of an extreme row or column of the plurality of dies 204. In the example of FIG. 5, Reference Die I is located at the left-most extreme column, Reference Die 2 is located at the right-most extreme column, Reference Die 3 is located at the top-most extreme row, and Reference Die 4 is located at the bottom-most extreme row. The reference dies 206 can have been located by the die detection sensor 12, such as by implementing a Die/No-Die check using the die detection algorithm 28. For example, the die detection sensor 12 can scan near the peripheral edge of the semiconductor wafer 202 to determine the location of at least one complete die, such that the extreme rows and columns are defined as being the respective rows and columns that are closest to the peripheral edge of the semiconductor wafer 202 that includes at least one complete die. As such, the at least one complete die located in the respective extreme rows and/or columns can be used as a reference die 206.

Upon determining the location of the reference dies 206, the wafermap alignment algorithm 30 can perform a theta count. For example, the wafermap alignment algorithm 30 can count the number of rows and/or columns of the plurality of dies 204 on the semiconductor wafer 202 based on the known physical locations of the reference dies 206. In the example of FIG. 5, a column theta count θ_{C} of the semiconductor wafer 202 results in eleven columns between Reference Die 1 and Reference Die 2. Likewise, a row theta count θ_{R} of the semiconductor wafer 202 results in eleven rows between Reference Die 3 and Reference Die 4. The column theta count θ_{C} and the row theta count θ_{R} can be compared with a number of rows and columns, respectively, associated with the wafermap 24. As a result, the wafermap 24 can be aligned with the semiconductor wafer 202 based on the comparison. In addition, the controller 18 could also prompt an error upon a discrepancy between the number of rows and/or columns of the wafermap 24 with the row theta count θ_{R} and/or the column theta count θ_{C}.

Determining the row theta count θ_{R} and/or the column theta count θ_{C} of the wafermap alignment algorithm 30 can be implemented instead of or in addition to the wafermap alignment algorithm 30 demonstrated in the example of FIG. 2 above. For example, the determination of the row theta count θ_{R} and/or the column theta count θ_{C} can be implemented to verify wafermap alignment after alignment based on determining a physical location of a single reference die. In addition, based on the known number of rows and columns of the semiconductor wafer 202, a center-to-center pitch measurement of the plurality of dies 204 can also be determined. In the example of FIG. 5, a column pitch measurement of X and a row pitch measurement of Y is determined. The column pitch measurement X and the row pitch measurement Y can be provided to other hardware, such as to a servo controller of pick-and-place hardware, thus allowing subsequent stages of IC manufacture to likewise be automated.

It is to be understood that the diagram 200 in the example of FIG. 5 is provided as a simplified example. For example, the semiconductor wafer 202 can include many more than eleven rows and columns in quantities that need not be equal relative to each other. In addition, it is to be understood that more than one complete die could occupy a given extreme column and/or row. As such, any of the complete dies in the given extreme column and/or row can be used as a reference die for the wafermap alignment algorithm.

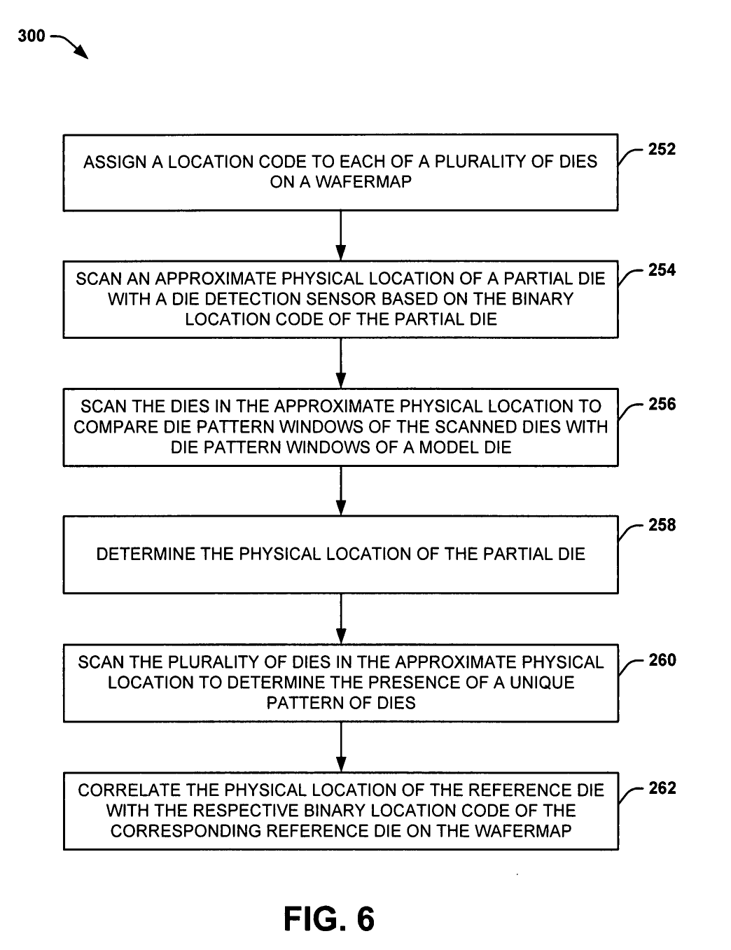

In view of the foregoing structural and functional features described above, certain methods will be better appreciated with reference to FIG. 6. It is to be understood and appreciated that the illustrated actions, in other embodiments, may occur in different orders and/or concurrently with other actions. Moreover, not all illustrated features may be required to implement a method. It is to be further understood that the following methodologies can be implemented in hardware (e.g., a computer or a computer network), software (e.g., as executable instructions running on one or more computer systems), or any combination of hardware and software.

FIG. 6 illustrates a method 250 for automatically aligning a wafermap with a semiconductor wafer in accordance with an aspect of the invention. At 252, a location code is assigned to each of a plurality of dies on a wafermap. Each of the plurality of dies on the wafermap can correspond to one of a plurality of dies on a semiconductor wafer. At 254, a die detection sensor scans an approximate physical location of a partial die based on the location code of the partial die. The partial/mirror die can have a physical location that is adjacent to a reference die, such that the die detection sensor is likewise moved to an approximate location of the reference die.

At 256, dies in the approximate physical location are scanned to compare die pattern windows of the scanned dies with die pattern windows of a model die. The die pattern windows can occupy the corners of each of the scanned dies, such as at all four corners of the dies or at two corners based on the quadrant in which a given scanned die is located. The comparison can provide a match score that is determinative of whether a given scanned die is a full die or a partial die. At 258, the physical location of the partial die is determined. The determination of the physical location of the partial die can be based on finding a partial die in the approximate physical location based on the location code.

At 260, a plurality of dies in the approximate location are scanned to determine the presence of a predetermined pattern of dies. The predetermined pattern of dies can be such that there is no other similar arrangement of dies on the semiconductor wafer near the partial die. Upon determining the presence of the predetermined pattern of dies, the physical location of the reference die can be known with certainty. At 262, the physical location of the reference die is correlated with the respective location code of the corresponding reference die on the wafermap. Therefore, the physical locations of each of the plurality of dies on the semiconductor wafer can be known with certainty.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications, and variations that fall within the spirit and scope of the appended claims.

What is claimed is:

1. A method for aligning a wafermap with a semiconductor wafer, the method comprising:
assigning a location code to each of a plurality of dies on the wafermap, each of the plurality of dies on the wafermap corresponding to each of a plurality of dies on the semiconductor wafer;
scanning an approximate location of a reference die on the semiconductor wafer with a die detection sensor based on the location code corresponding to a location of the reference die on the wafermap;
determining a physical location of the reference die on the semiconductor wafer using the die detection sensor; and
correlating the physical location of the reference die on the semiconductor wafer with the respective location code corresponding to the reference die on the wafermap.

2. The method of claim 1, wherein scanning the approximate location of the reference die comprises scanning an approximate location associated with a partial die located adjacent to the reference die based on a location code corresponding to the partial die.

3. The method of claim 2, wherein determining the physical location of the reference die comprises verifying the location associated with the partial die based on scanning a portion of the plurality of dies on the semiconductor wafer surrounding the partial die, the portion of the plurality of dies being arranged in a predetermined pattern on the semiconductor wafer.

4. The method of claim 1, wherein determining the physical location of the reference die comprises comparing an image pattern associated with four corners of each of a portion of the plurality of dies on the semiconductor wafer located at the approximate location of the reference die with a predetermined image pattern associated with four corners of a model die.

5. The method of claim 4, wherein comparing the image pattern comprises implementing a gray-scale pattern recognition algorithm to compare the four corners of each of the portion of the plurality of dies and the four corners of the model die, the method further comprising:
generating a match score based on the comparison of the four corners of each of the portion of the plurality of dies and the four corners of the model die;
comparing the match score relative to a threshold value; and
identifying a given one of the portion of the plurality of dies as a partial die based on the comparison of the match score.

6. The method of claim 1, further comprising verifying locations associated with a plurality of partial dies at a periphery of the semiconductor wafer based on a comparison of two diagonally opposite corners of each of a portion of the plurality of dies on the semiconductor wafer located approximately at the periphery of the semiconductor wafer with a predetermined image pattern associated with two diagonally opposite corners of a model die.

7. The method of claim 6, wherein verifying locations comprises dividing the semiconductor wafer into quadrants defined by a coordinate system, the coordinate system being substantially centered on the semiconductor wafer, such that a line intersecting the two diagonally opposite corners of each die in a respective one of the quadrants intersects a portion of the periphery of the semiconductor wafer, the portion of the periphery being defined by the respective one of the quadrants.

8. The method of claim 1, wherein determining the physical location of the reference die comprises determining a physical location of at least one pair of reference dies, each of the at least one pair of reference dies being located at opposite extremes of at least one of rows and columns associated with the plurality of dies on the semiconductor wafer, the opposite extremes of the at least one of the rows and the columns including at least one complete die.

9. The method of claim 8, further comprising:
comparing a number of the at least one of rows and columns associated with the plurality of dies on the semiconductor wafer with a number of a respective at least one of rows and columns on the wafermap; and
calculating a center-to-center pitch associated with the plurality of dies on the semiconductor wafer upon a match associated with the comparison of the number of the at least one of rows and columns.

10. A wafermap alignment system comprising:
a die detection sensor configured to sense an image pattern associated with four corners of a plurality of dies on a semiconductor wafer;
a memory configured to store data representing a predetermined image pattern associated with four corners of a model die and a location code associated with a location of at least one reference die on a wafermap; and
a controller configured to implement a die detection algorithm to determine a physical location of the at least one reference die based on a comparison of the image pattern associated with the four corners of the plurality of dies with the predetermined image pattern, and to correlate the physical location of the at least one reference die with the location code associated with the location of the at least one reference die on the wafermap.

11. The system of claim 10, wherein the controller is configured to command the die detection sensor to scan an approximate location of the at least one reference die based on the location code associated with the location of the at least one reference die on the wafermap, and wherein the die detection algorithm is configured to detect the physical location of a partial die located adjacent to the at least one reference die and a predetermined pattern of dies surrounding the at least one reference die.

12. The system of claim 11, wherein the die detection algorithm comprises a gray-scale pattern recognition algorithm that generates a match score associated with the comparison of the four corners of the plurality of dies relative to the four corners of the model die and identifies a given one of the plurality of dies as a partial die based on a comparison of the given one of the plurality of dies relative to a threshold value.

13. The system of claim 10, wherein the die detection sensor is further configured to sense an image pattern associated with two diagonally opposite corners of a portion of the plurality of dies on the semiconductor wafer, and the controller is further configured to divide the semiconductor wafer into quadrants and to verify locations associated with a plurality of partial dies at a periphery of the semiconductor wafer based on a comparison of the two diagonally opposite corners of each of the portion of the plurality of dies located approximately at the periphery with a predetermined image pattern associated with two diagonally opposite corners of the model die, wherein a line extending through the two diagonally opposite corners of each of the portion of the plurality of dies intersects a portion of the periphery of the semiconductor wafer, the portion of the periphery being defined by the respective one of the quadrants.

14. The system of claim 10, wherein the at least one reference die comprises at least one pair of reference dies located at opposite extremes of at least one of rows and columns associated with the plurality of dies on the semiconductor wafer, the opposite extremes of the at least one of the rows and the columns including at least one complete die, the controller being further configured to compare a number of the at least one of rows and columns associated with the plurality of dies on the semiconductor wafer with a number of a respective at least one of rows and columns on the wafermap.

15. A method for aligning a wafermap with a semiconductor wafer, the method comprising:
assigning a location code to each of a plurality of dies on the wafermap, each of the plurality of dies on the wafermap corresponding to each of a plurality of dies on the semiconductor wafer;
scanning an approximate location of a partial die on the semiconductor wafer with a die detection sensor based on the location code corresponding to a location of the partial die on the wafermap, the partial die being adjacent to a reference die on the semiconductor wafer;
determining a physical location of the partial die;
determining a physical location of the reference die on the semiconductor wafer based on the physical location of the partial die and a predetermined pattern of dies arranged near the location associated with the partial die; and
correlating the physical location of the reference die on the semiconductor wafer with the respective location code corresponding to the reference die on the wafermap.

16. The method of claim 15, wherein determining the physical location of the partial die comprises comparing an image pattern associated with four corners of each of a portion of the plurality of dies on the semiconductor wafer located at the approximate location of the reference die with a predetermined image pattern associated with four corners of a model die.

17. The method of claim 16, wherein comparing the image pattern comprises:
implementing a gray-scale pattern recognition algorithm to generate a match score associated with the comparison of the four corners of each of the portion of the plurality of dies and the four corners of the model die; and
identifying a given one of the portion of the plurality of dies as a respective partial die based on a comparison of the match score relative to a threshold value.

18. The method of claim 15, further comprising:
dividing the semiconductor wafer into quadrants defined by a coordinate system, the coordinate system being substantially centered on the semiconductor wafer; and
verifying locations of a plurality of partial dies at a periphery of the semiconductor wafer based on a comparison of two diagonally opposite corners of each of a portion of the plurality of dies on the semiconductor wafer located approximately at the periphery of the semiconductor wafer with a predetermined image pattern associated with two diagonally opposite corners of a model die, wherein a line extending through the two diagonally opposite corners of each of the portion of the plurality of dies intersects a portion of the periphery of the semiconductor wafer, the portion of the periphery being defined by the respective one of the quadrants.

19. The method of claim 15, wherein determining the physical location of the reference die comprises determining a physical location of at least one pair of reference dies, each of the at least one pair of reference dies on the semiconductor wafer being located at opposite extremes of at least one of rows and columns associated with the plurality of dies on the semiconductor wafer, the opposite extremes of the at least one of the rows and the columns including at least one complete die.

20. The method of claim 19, further comprising:
comparing a number of the at least one of rows and columns associated with the plurality of dies on the semiconductor wafer with a number of a respective at least one of rows and columns on the wafermap; and
calculating a center-to-center pitch associated with the plurality of dies on the semiconductor wafer upon a match associated with the comparison of the number of the at least one of rows and columns.
